(19) United States
(12) Patent Application Publication
(10) Pub. No.: US 2017/0236887 A1
(43) Pub. Date: Aug. 17, 2017

(54) METHOD FOR MANUFACTURING ORGANIC EL DISPLAY PANEL, AND ORGANIC EL DISPLAY PANEL

(71) Applicant: JOLED INC., Tokyo (JP)

(72) Inventors: Shinichiro HASHIMOTO, Tokyo (JP); Shinya ONO, Osaka (JP)

(73) Assignee: JOLED INC., Tokyo (JP)

(21) Appl. No.: 15/518,786

(22) PCT Filed: Sep. 29, 2015
(86) PCT No.: PCT/JP2015/004957

§ 371 Date: Apr. 13, 2017

(30) Foreign Application Priority Data
Oct. 15, 2014 (JP) 2014-211113

(51) Int. Cl. H01L 27/32; H01L 27/12; H01L 51/56; G09F 9/33

(52) U.S. Cl. CPC H01L 27/3262; G09F 9/33; H01L 27/1225; H01L 27/124; H01L 27/1259; H01L 51/56

(57) ABSTRACT

A method for manufacturing an organic EL display panel that includes: forming, on a substrate, a first pattern that includes gate electrodes, scan lines, and a first common line; forming, above the substrate, a second pattern that includes source electrodes, drain electrodes, data lines, and first disconnect parts that disconnect the data lines and the first common line; conducting an open-short test for the data lines; and forming, above the substrate, a third pattern that includes first bridge lines that extend over the corresponding first disconnect parts to connect the data lines and the first common line.

### TECHNICAL FIELD

The present disclosure relates to a method for manufacturing an organic electro luminescence (EL) display panel that displays an image by causing organic ELs to emit light based on transistors formed in a matrix on a substrate, and relates to an organic EL display panel.

### BACKGROUND ART

Conventional display panels that include organic ELs apply electrical currents to individual organic ELs (pixels) disposed in a matrix to cause them to emit light. Such display panels display color images (video) by controlling the luminescence colors and brightness of the pixels. Organic ELs emitting red light, green light, and blue light, which form these pixels, are referred to as subpixels, and are driven under the control of plural thin film transistors (TFTs) and the like.

As described above, a large number of TFTs are disposed in a matrix (referred to as a TFT array) for driving the individual subpixels. A TFT array is a stack of plural layers on a substrate including for example: semiconductors formed from low-temperature polysilicon or amorphous silicon (a-Si); line materials; and insulators that isolate individual layers from one another.

The manufacturing of a TFT array includes processes such as lamination of layers and etching, during which a defect in the TFT array can be inspected by use of an inspection device or the like. For example, Patent Literature (PTL) 1 describes a method for testing the performance of a TFT array prior to the formation of organic ELs. More specifically, PTL 1 discloses a method for detecting open-short defects in a driving TFT of the TFT array prior to the mounting of organic ELs.

### CITATION LIST

### Patent Literature

### [PTL 1] Japanese Unexamined Patent Application Publication No. 2004-347749

### SUMMARY OF INVENTION

### Technical Problem

The increasingly higher resolution of the current display panels means that line materials, which run in stripes throughout such display panels, are more finely and densely formed. Hence, it is desirable that defects, such as line breaks and short circuits between adjacent lines, be also detected in addition to defects in a TFT itself.

In view of this, the conventional open-short test for lines has been conducted in a way that a TFT array is placed on a stage, across which a predetermined voltage, including a ground voltage, is applied.

However, the inventors have found that the conventional method fails to conduct an effective open-short test for lines in the case where a transparent amorphous oxide semiconductor (TAOS) is used, for example, as a semiconductor to form a TFT with a desired performance. This is because, when the TFT array is placed on a stage under the application of a predetermined voltage, each TFT turns on (a state in which an electrical current flows between the source and the drain), meaning that lines are electrically continuous with one another.

The present disclosure is based on the above-described finding of the inventors, and its object is to provide a method for manufacturing an organic EL display panel that enables an open-short test for lines to be effectively conducted even in the case where such display panel includes TFTs formed of amorphous oxide semiconductors, and to provide such organic EL display panel.

### Solution to Problem

To achieve the above object, the method for manufacturing an organic EL display panel according to the present disclosure is a method for manufacturing an organic EL display panel including selection transistors each having a channel that includes an amorphous oxide semiconductor. Such method includes: forming, on a substrate which is an insulator, a first pattern that includes gate electrodes of the selection transistors, scan lines connected to the gate electrodes, and a first common line; forming, above the substrate, a second pattern that includes source electrodes of the selection transistors, drain electrodes of the selection transistors, data lines connected to the source electrodes, and first disconnect parts that disconnect the data lines and the first common line; conducting an open-short test for the data lines; and forming, above the substrate, a third pattern that includes first bridge lines that connect the data lines and the first common line, each of the first bridge lines extending over a corresponding one of the first disconnect parts.

Moreover, to achieve the above object, the organic EL display panel according to the present disclosure is an organic EL display panel that includes selection transistors each having a channel that includes an amorphous oxide semiconductor. Such organic EL display panel includes: a substrate which is an insulator; a first pattern that includes gate electrodes of the selection transistors, scan lines connected to the gate electrodes, and a first common line; a second pattern that includes source electrodes of the selection transistors, drain electrodes of the selection transistors, data lines connected to the source electrodes, and first disconnect parts that disconnect the data lines and the first common line; and a third pattern that includes first bridge lines that connect the data lines and the first common line, each of the first bridge lines extending over a corresponding one of the first disconnect parts.

### Advantageous Effects of Invention

The present disclosure allows an open-short test for data lines to be effectively conducted in the manufacturing an organic EL display panel.

### BRIEF DESCRIPTION OF DRAWINGS

FIG. 1 is a circuit diagram showing a part of a TFT array according to an embodiment.

FIG. 2 is a cross-sectional view showing the structure of a selection transistor.

FIG. 3 is a plan view showing a first pattern resulted from a first patterning process.

FIG. 4 is a plan view showing the first pattern formed on the periphery of a substrate.

FIG. 5 is a cross-sectional view showing one process included in the first patterning process.

FIG. 6 is a cross-sectional view showing one process included in the first patterning process.

FIG. 7 is a cross-sectional view showing one process included in the first patterning process.

FIG. 8 is a cross-sectional view showing a state in which a first insulating layer has been formed through a first insulating layer forming process.

FIG. 9 is a plan view showing a pattern resulted from a channel forming process.

FIG. 10 is a cross-sectional view showing one process included in the channel forming process.

FIG. 11 is a cross-sectional view showing one process included in the channel forming process.

FIG. 12 is a cross-sectional view showing a state in which a second insulating layer has been formed on the first insulating layer through a second insulating layer forming process.

FIG. 13 is plan view showing a pattern of first contact holes resulted from a first contact hole forming process.

FIG. 14 is a cross-sectional view showing the selection transistor after the first contact hole forming process is completed.

FIG. 15 is a plan view showing a line pattern resulted from a second patterning process.

FIG. 16 is a plan view showing a second pattern formed on the periphery of the substrate.

FIG. 17 is a cross-sectional view showing the selection transistor after the second patterning process is completed.

FIG. 18 is a perspective view showing an open-short test being conducted for data lines.

FIG. 19 is a cross-sectional view showing a state in which a third insulating layer has been formed on the second insulating layer through a third insulating layer forming process.

FIG. 20 is a cross-sectional view showing part of the selection transistor after the second contact hole forming process is completed.

FIG. 21 is a plan view showing a line pattern resulted from a third patterning process.

FIG. 22 is a plan view showing a third pattern formed on the periphery of the substrate.

FIG. 23 is a cross-sectional view showing a part of the selection transistor after the third patterning process is completed.

### DESCRIPTION OF EMBODIMENT

The following describes an embodiment of the method for manufacturing an organic EL display panel according to the present disclosure with reference to the drawings. Note that the following embodiment is an exemplary illustration of the method for manufacturing an organic EL display panel and the organic EL display panel according to the present disclosure. Therefore, the scope of the present disclosure is limited by the language recited in Claims with reference to the following embodiment, and thus is not limited only to the following embodiment. Of the elements described in the following embodiment, elements not recited in any one of the independent claims that indicate the broadest concepts of the present disclosure are not necessarily required to achieve the object of the present disclosure, and thus are described as elements for achieving a more preferred mode.

Also note that the drawings are schematic diagrams, and thus they are not necessarily precise illustrations.

### Embodiment 1

The method for manufacturing an organic EL display panel and the organic EL display panel according to the present embodiment are described below with reference to the drawings.

### Structure of TFT Array

First, the structure of a TFT array 101 is described that forms a part of an organic EL display panel 100 manufactured by the manufacturing method according to the present embodiment.

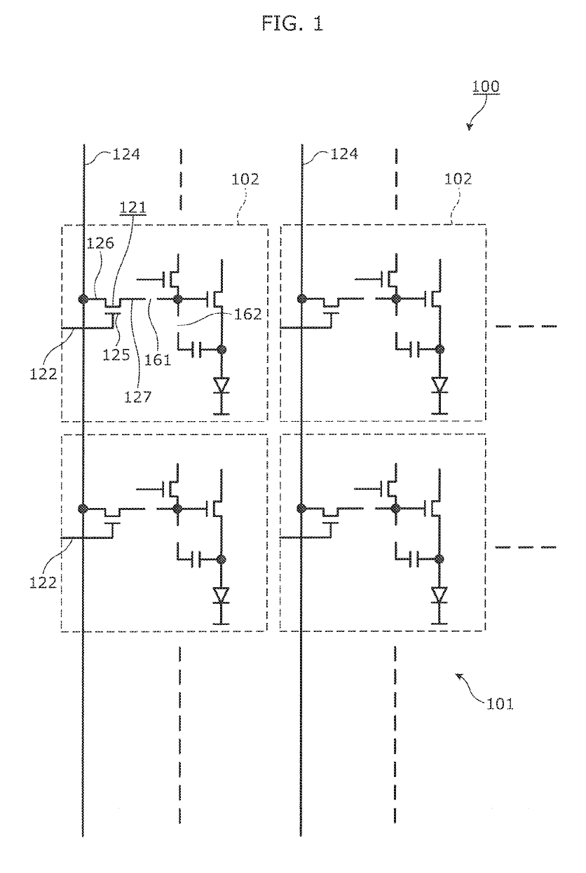

FIG. 1 is a circuit diagram showing a part of the TFT array according to the present embodiment.

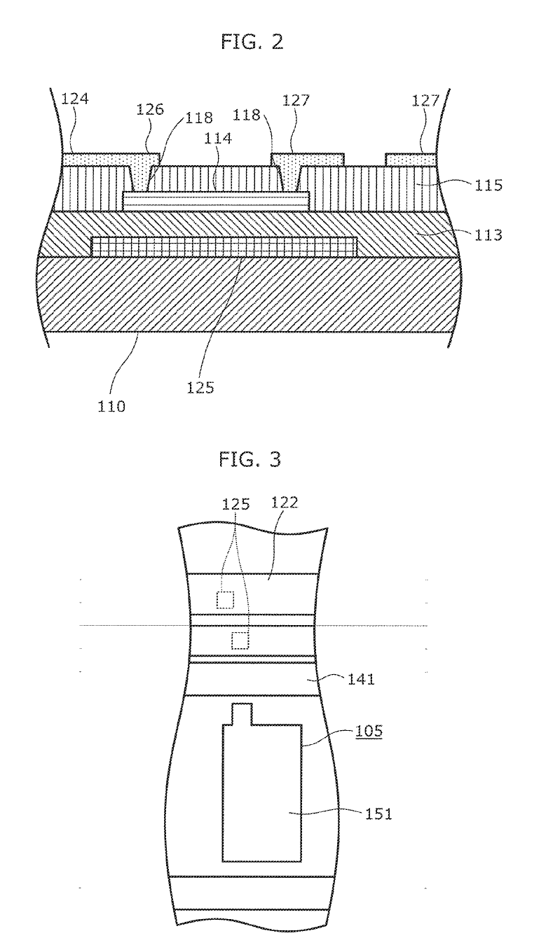

FIG. 2 is a cross-sectional view showing the structure of a selection transistor. Note that other transistors may have a similar structure.

As FIG. 1 shows, the TFT array 101 includes thin-film transistors formed in a matrix. Note that this drawing shows a circuitry state of the TFT array 101 before an open-short test is conducted.

The TFT array 101 includes plural transistors including selection transistors 121 corresponding one-to-one to subpixels 102, and further includes scan lines 122 and data lines 124 that run over the plural subpixels 102. Further, as FIG. 2 shows, each selection transistor 121 is a transistor formed in a thin-film form on a substrate 110, and includes a gate electrode 125, a source electrode 126, a drain electrode 127, a first insulating layer 113, a channel forming layer 114, and a second insulating layer 115.

Each selection transistor 121 is a thin-film transistor in which its gate electrode 125 is connected to the scan line 122 and its source electrode 126 is connected to the data line 124, and is a transistor that selects whether or not to supply a capacitor with an image signal transmitted through the data lines 124, based on a scan signal transmitted through the scan lines 122, The present embodiment adopts a bottom-gate transistor as each selection transistor 121.

Any material with the insulating properties may be used as the material of the substrate 110, and thus the substrate 110 may be formed, for example, from: a glass material such as quartz glass, alkali-free glass, and high heat resistant glass; or a resin material such as polyethylene, polypropylene, and polyimide. Further, the substrate 110 may be not only a flexible substrate, but also a rigid substrate with relatively high rigidity.

The gate electrode 125 is an electrode with a single-layer or multi-layer structure formed from an electrically conductive film made of an electrically conductive material, and is formed in a predetermined form above the substrate 110. Any material may be used as the material of the gate electrode 125, and thus the material may, for example, be: a metal or an alloy of plural metals (e.g., molybdenum tungsten), an electrically conductive metal oxide such as indium tin oxide (ITO), aluminum-doped zinc oxide (AZO), and gallium-doped zinc oxide (GZO); or an electrically conductive polymeric material such as polythiophene and polyacetylene.

The first insulating layer 113, which is a member for insulating the gate electrode 125 and the channel forming layer 114 from each other, is disposed between the gate electrode 125 and the channel forming layer 114 to extend in a sheet form across the entirety of the substrate 110. Any material with the electrically insulating properties may be used as the material of the first insulating layer 113, and thus the material may, for example, be: a single-layer film such as that of a silicon dioxide film, a silicon nitride film, a silicon oxynitride film, an aluminum oxide film, a tantalum oxide film, and a hafnium oxide film; or a multi-layer film that is formed of a laminate of one or more of these films.

The channel forming layer 114 is a portion formed of an amorphous oxide semiconductor, and is formed on the first insulating layer 113 in a predetermined form above the gate electrode 125. The present embodiment uses a transparent amorphous oxide semiconductor (TAOS) as the material of the channel forming layer 114. The metal element that forms the channel forming layer 114 is, for example, indium (In), tungsten (W), gallium (Ga), or zinc (Zn).

The second insulating layer 115 is an interlayer insulating layer that is disposed on the first insulating layer 113 to cover the channel forming layer 114 and that extends in a sheet form across the entirety of the substrate 110.

Any material with the electrically insulating properties may be used as the material of the second insulating layer 115, and thus the material may, for example, be: a single-layer film such as that of a silicon dioxide film, a silicon nitride film, a silicon oxynitride film, and an aluminum oxide film; or a multi-layer film that is formed of a laminate of one or more of these films.

Further, first contact holes 118 are formed, in the second insulating layer 115, that partially pass through the second insulating layer 115. The channel forming layer 114 is connected to the source electrode 126 and the drain electrode 127 via these first contact holes 118 in the second insulating layer 115.

The source electrode 126 and the drain electrode 127 are electrodes that are formed above the second insulating layer 115. More specifically, the source electrode 126 and the drain electrode 127 are formed on the second insulating layer 115 such that these electrodes are facing and spaced apart from each other in the direction parallel to the substrate 110 (in a horizontal direction of the substrate), and that these electrodes are connected to the channel forming layer 114 via the first contact holes 118 formed in the second insulating layer 115.

Any material with the electrically conductive properties may be used as the material of the source electrode 126 and the drain electrode 127, and thus the material may be, for example, aluminum, tantalum, molybdenum, tungsten, silver, copper, titanium, or chrome. Further, the source electrode 126 and the drain electrode 127 may not only be electrodes with a multi-layer structure but also with a single-layer structure.

The scan lines 122 are lines that are connected to the gate electrodes 125 of the selection transistors 121 and that transmit a scan signal for displaying an image. In response to the supply of a scan signal to the scan lines 122, the source electrodes 126 and the drain electrodes 127 of the corresponding selection transistors 121 becomes electrically continuous, i.e., the selection transistors 121 turn on. The scan lines 122 are connected to the gate electrodes 125 of the selection transistors 121. Plural scan lines 122 are arranged in a row to intersect with data lines 124.

The data lines 124 are lines that are connected to the corresponding source electrodes 126 included in an array of the selection transistors 121, and that transmit an image signal. Plural data lines 124 are arranged in a row to intersect with the scan lines 122, and to extend from one end to the other end of the TFT array 101. Note that the open-short test according to the present disclosure inspects whether each data line 124 is short-circuited with another line (e.g., a line used for an adjacent subpixel) or whether each data line 124 is broken.

### Processes of Manufacturing TFT Array

The following describes the processes of manufacturing the TFT array 101 with reference to the drawings.

First, a first patterning process is described. The first patterning process refers to a process of forming: gate electrodes 125 of each selection transistor 121 and another transistor; a scan line 122 connected to the gate electrodes; a first common line 141; a first electrode 151 that forms a capacitor 105; and other lines. In the first patterning process according to the present embodiment, a second common line 142 that extends along the scan line 122 and that intersects with the data line 124 is also formed on the periphery of the substrate 110.

FIG. 3 is a plan view showing a first pattern resulted from the first patterning process.

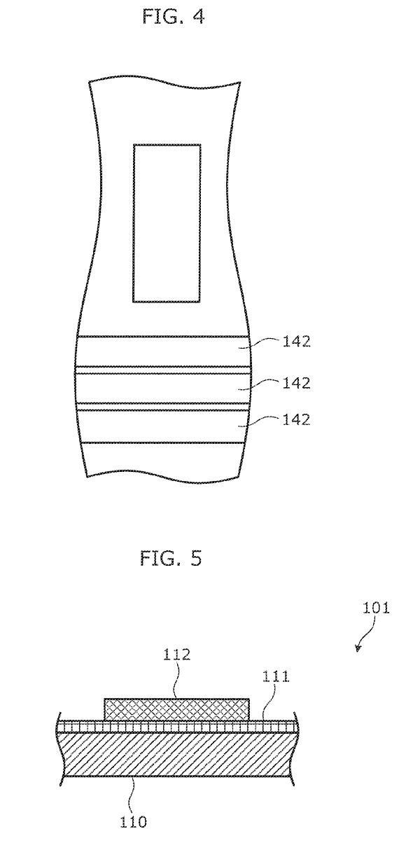

FIG. 4 is a plan view showing the first pattern formed on the periphery of the substrate.

FIGS. 5 to 7 are cross-sectional views showing one process included in the first patterning process.

First, as FIG. 5 shows, a conductive film 111 is formed across the entirety of the upper surface of the substrate 110 through a technique such as sputtering. The conductive film may have, for example, a multi-layer structure of copper and molybdenum.

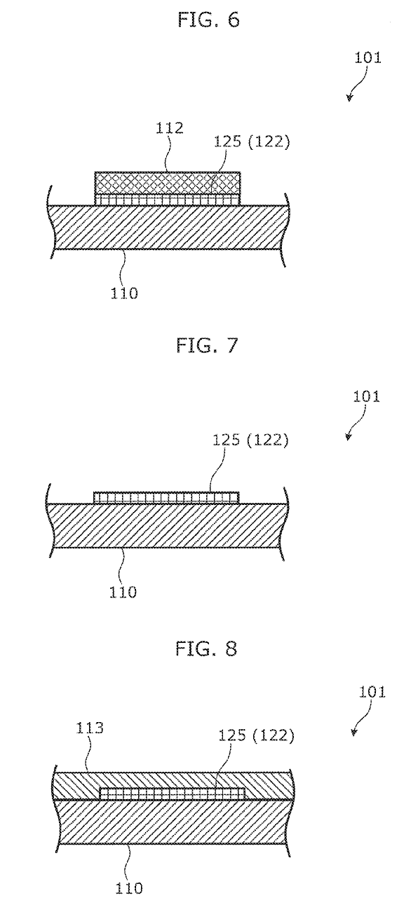

Next, as FIG. 6 shows, a pattern of a photoresist 112 is formed on the surface of the conductive film 111 through a technique such as photolithography. The pattern of the photoresist 112 is the same as the first pattern to remain protected in the subsequent etching process.

Next, portions of the conductive film 111 on which the photoresist 112 is not formed are etched through a technique such as wet-etching.

Next, as FIG. 7 shows, the removal of the photoresist 112 results in the first pattern shown in FIG. 3 that includes the gate electrode 125 of the selection transistor 121, the scan line 122 connected to the gate electrode 125, the first common line 141, and the capacitor 105 that forms the first electrode 151. In the present embodiment, the gate electrode 125 and the scan line 122 are integrally formed. The second common lines 142 are also formed.

Here, the first common line 141 refers to a reference voltage line that applies a reference voltage, for example, across the capacitor 105.

Each of the second common lines 142 refers to a line that is disposed outside of the pixel region to, for example, protect the pixels from static electricity, and that connects subpixels of the same color.

The following describes a first insulating layer forming process.

FIG. 8 is a cross-sectional view showing a state in which the first insulating layer has been formed through the first insulating layer forming process.

The first insulating layer forming process refers to a process of forming the first insulating layer 113 (gate insulating film) to be disposed in a sheet form to cover the first pattern formed from an electrically conductive material. Any method may be used to form the first insulating layer 113, and thus the method may be, for example, chemical vapor deposition (CVD).

The following describes a channel forming process. The channel forming process refers to a process of forming the channel forming layer 114.

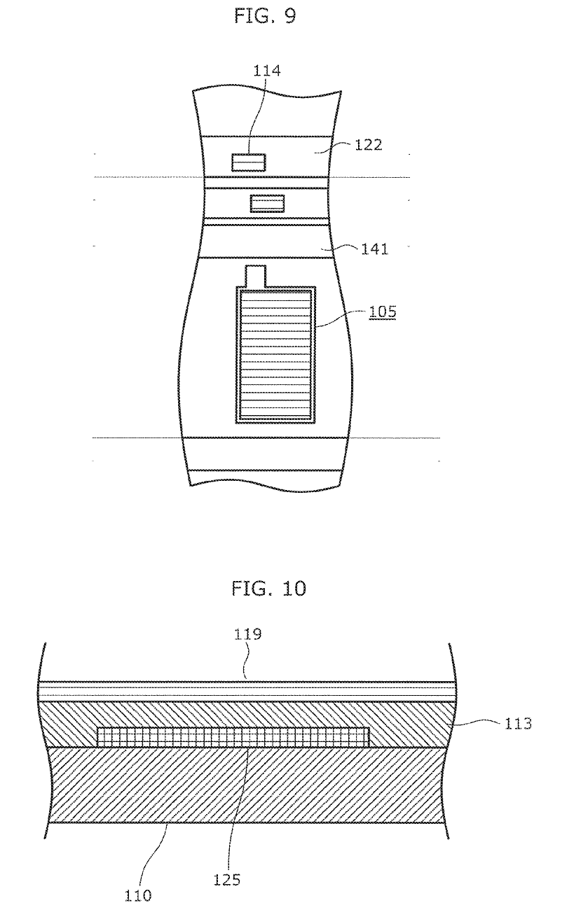

FIG. 9 is a plan view showing a pattern resulted from the channel forming process.

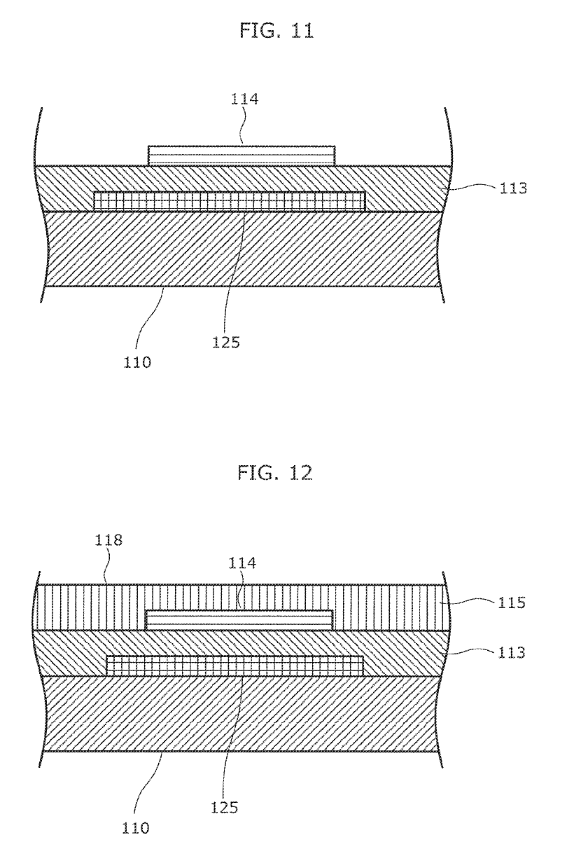

FIGS. 10 and 11 are cross-sectional views showing one process included in the channel forming process.

First, as FIG. 10 shows, an amorphous oxide semiconductor film 119, which serves as the channel forming layer, is formed over the first insulating layer 113 that has been formed through the first insulating layer forming process, such that the amorphous oxide semiconductor film 119 extends across the entirety of the substrate 110. In the present embodiment, a TAOS is formed as the amorphous oxide semiconductor film 119 through a technique such as sputtering.

Next, a photoresist pattern is formed on the surface of the amorphous oxide semiconductor film 119 through a technique such as photolithography, as in the case of forming the pattern including the gate electrode 125 and the like, and unnecessary portions are subsequently etched through a technique such as wet-etching.

This results in the channel forming layer 114 that faces the gate electrode 125 across the first insulating layer 113, as shown in FIG. 11.

The following describes a second insulating layer forming process.

FIG. 12 is a cross-sectional view showing a state in which the second insulating layer has been formed on the first insulating layer through the second insulating layer forming process.

The second insulating layer forming process refers to a process of forming the second insulating layer 115 (channel protective film) to be disposed, in a sheet form, to cover the channel forming layer 114 that has been disposed, in an island form, on the surface of the first insulating layer 113. Any method may be used to form the second insulating layer 115, as in the case of forming the first insulating layer 113.

The following describes a first contact hole forming process.

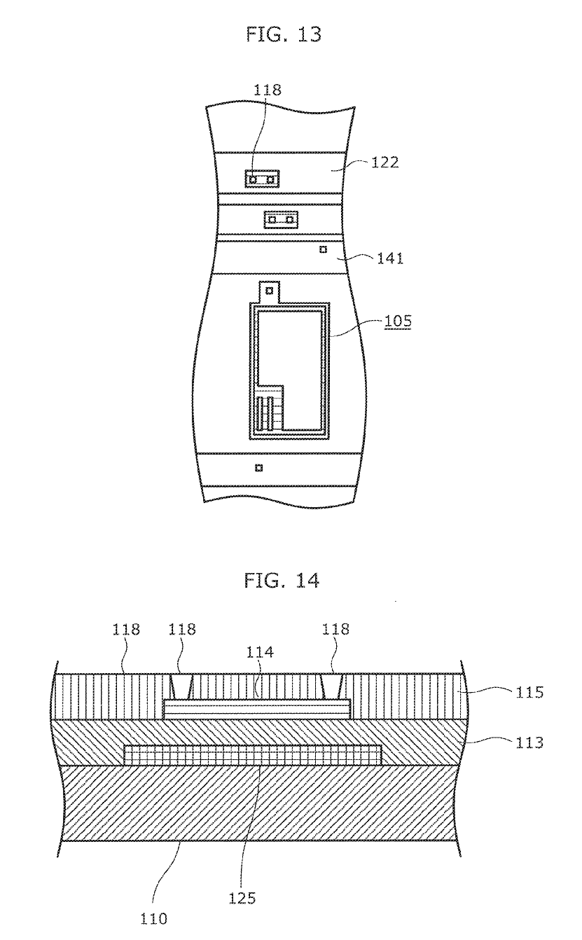

FIG. 13 is plan view showing a pattern of first contact holes resulted from the first contact hole forming process.

FIG. 14 is a cross-sectional view showing the selection transistor after the first contact hole forming process is completed.

The first contact holes 118 are holes, each passing through an insulating layer in a thickness direction to connect a pattern and the channel and to connect patterns in different layers. Example through holes include: a first contact hole 118 that passes through the second insulating layer 115 in a thickness direction to reach the channel forming layer 114; and a through hole that passes through the second insulating layer 115 and the first insulating layer 113 in a thickness direction to reach the first pattern.

The first contact holes 118 are created by forming a photoresist pattern on the surface of the second insulating layer 115 through a technique such as photolithography, as in the case of forming the first pattern including the gate electrode 125 and the like, and subsequently by using a technique such as dry-etching.

This results in the first contact holes 118 that pass through the second insulating layer 115 in a thickness direction to reach the channel forming layer 114, as shown in FIG. 14.

The following describes a second patterning process.

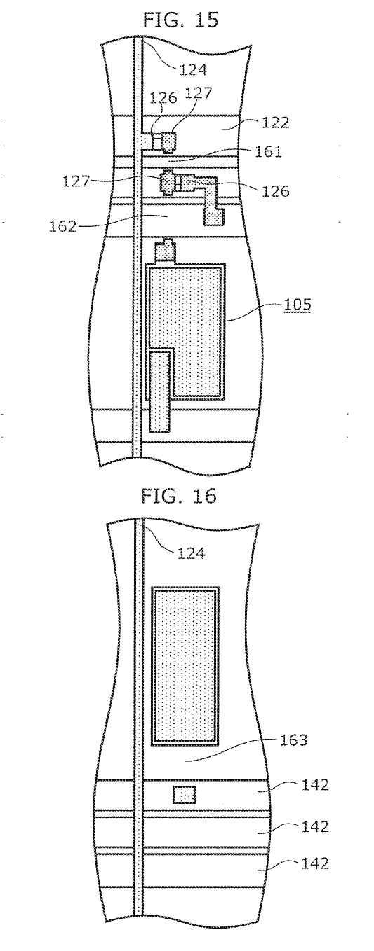

FIG. 15 is a plan view showing a line pattern resulted from the second patterning process.

FIG. 16 is a plan view showing a second pattern formed on the periphery of the substrate.

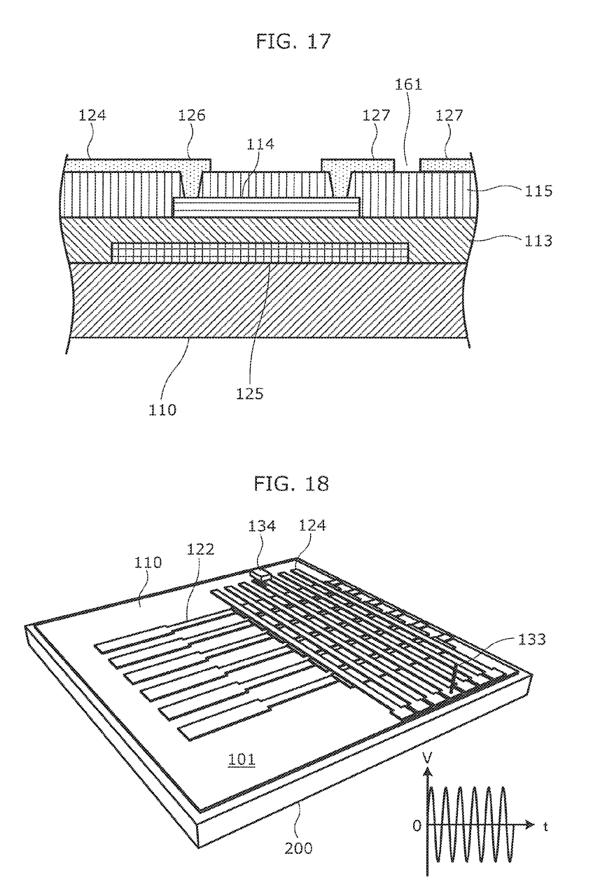

FIG. 17 is a cross-sectional view showing the selection transistor after the second patterning process is completed.

The second patterning process refers to a process of forming on the second insulating layer 115: a source electrode 126 and a drain electrode 127 of each selection transistor 121; a data line 124; a first disconnect part 161 that disconnects the data line 124 and the first common line 141 included in the first pattern; and the like. Note that the second pattern also includes the source electrode and the drain electrode of another transistor, and thus FIG. 17 (also FIG. 2) also shows the drain electrode 127 of another transistor (reference transistor in the present embodiment).

In the second patterning process according to the present embodiment, a second disconnect part 162 that is discontinuous with the first disconnect part 161 is also formed between the drain electrode 127 of the selection transistor 121 and the capacitor 105. Also formed in the second patterning process is a third disconnect part 163 that disconnects the data line 124 and the second common lines 142 that are disposed on the periphery of the substrate 110, e.g., outside of the image display region.

Here, “disconnects the data line 124 and the first common line 141” means that the data line 124 and the first common line 141 are electrically disconnected from each other in the second pattern. In this case, the source electrode and the drain electrode of the transistor is electrically connected regardless of a state of the channel. The same applies to the case of the “third disconnect part 163 that disconnects the data line 124 and the second common lines 142.”

Further, the first disconnect part 161 refers to a part that is electrically disconnected in the second pattern, but that is electrically connected for certain in the third pattern. The same applies to the second disconnect part 162 and the third disconnect part 163.

In the present embodiment, the first disconnect part 161 is disposed in the proximity of the drain electrode 127 of each selection transistor 121, i.e., disposed between the drain electrode 127 of the selection transistor 121 and the drain electrode 127 of another transistor. Alternatively, the first disconnect part 161 may be disposed between the data line 124 and the source electrode 126 of each selection transistor 121. Disposing of the first disconnect part 161 in the closest possible proximity of the data line 124 results in a more stable impedance of the data lines 124 and allows for an open-short test with higher accuracy.

The first disconnect part 161, the second disconnect part 162, and the third disconnect part 163 are disposed at the borders between the portions where the first pattern is formed and the portions where the first pattern is not formed. More specially, these disconnect parts are disposed to extend over the stepped portions generated by the first pattern. Especially, the second disconnect part 162 and the third disconnect part 163 are disposed to extend over plural stepped portions.

The following more specifically describes the second patterning process.

An electrically conductive film is formed across the entirety of the surface of the second insulating layer 115 through a technique such as sputtering, as in the case of forming the first pattern. This results in the conductive film disposed also on the inner periphery of each of the first contact holes 118, bringing the conductive film to come into contact with a part of the channel forming layer 114 and a part of the first pattern. Next, a photoresist pattern is formed on the surface of the conductive film through a technique such as photolithography. Unnecessary portions of the conductive film are subsequently etched through a technique such as wet-etching. Here, no photoresist pattern is formed on the first disconnect part 161, the second disconnect part 162, and the third disconnect part 163, and the conductive film of these parts are removed through etching.

This results in the second pattern that includes the disconnect parts as shown by the hatched parts in FIGS. 15 and 16.

Each of the data lines 124 formed through the above process are in a state of being disconnected from the first common line 141 and second common lines 142 by the first disconnect part 161 and the third disconnect part 163. More specifically, each single data line 124 is electrically disconnected from one another, and thus is in a floating state.

### Open-Short Test

The following describes an open-short test for the data lines 124.

FIG. 18 is a perspective view showing the open-short test being conducted for the data lines.

As the drawing shows, the TFT array 101 is placed on a stage 200 with the substrate 110 down on the stage 200. Formed on the substrate 110 of such TFT array 101 are: plural data lines 124 that have been formed through the second patterning process to have a floating structure; the selection transistors 121 and other transistors; the first pattern; and the like.

Such floating structure of the data lines 124 allows the open-short test to be effectively conducted, even in the case where the threshold voltage of the channel forming layer 114 of each selection transistor 121 is negative and the source electrode 126 and the drain electrode 127 are in electrical continuity.

Next, the open-short test is conducted for the data lines 124. Any method may be used as the open-short test, and thus the open-short test may include only an open circuit test and only a short circuit test. A test device used for the open-short test according to the present embodiment is equipped with: a charging terminal 133 capable of applying an alternating-current voltage of a predetermined frequency through contacting with a data line; and a power receiving sensor 134 capable of measuring a potential change of lines without contacting with a data line (by capacitive coupling).

Such test device conducts the open-short test as follows: brings the charging terminal 133 into contact with one end of a data line 124, and places the power receiving sensor 134 in the proximity (that allows for capacitive coupling) of the other end of the data line 124; and applies an alternating-current voltage of a predetermined frequency to one end of the data line 124 via the charging terminal 133. As a result, the power receiving sensor 134 obtains a potential change corresponding to the applied alternating-current voltage, in the case where the data line 124 is in a favorable state of neither broken nor short-circuited. On the other hand, the power receiving sensor 134 obtains a potential change that is different from a potential change for a favorable case, in the case where the data line is broken or short-circuited. The open-short test for the data lines 124 is conducted by observing potential changes in the above-described manner.

Such open-short test is conducted for each of the data lines 124. For example, the open-short test is conducted one by one for the data lines 124 that are arranged in stripes, by moving the charging terminal 133 and the power receiving sensor 134 relatively to the stage 200, with the stage 200 and the TFT array 101 placed on the stage 200 being fixed.

Note that the charging terminal 133 may or may not contact with the data lines 124, and the power receiving sensor 134 also may or may not contact with the data lines 124. Alternatively, any combination of these may be applicable.

As described above, it is possible to conduct an open-short test for the data lines 124 with each data line being electrically isolated from one another, even in the case where an amorphous oxide semiconductor with a negative threshold voltage is used as the channel forming layer 114. This enables the manufacturing of the organic EL display panel 100 that includes a TFT array 101 having the data lines 124 with no break or short circuit, and thus increases the yield of the organic EL display panel 100.

A TFT array 101 in which any defects have been detected by the above open-short test is to be repaired, where possible.

A TFT array 101 with no defects found and a TFT array 101 that has been repaired are subsequently subjected to the following third insulating layer forming process.

The following describes the third insulating layer forming process.

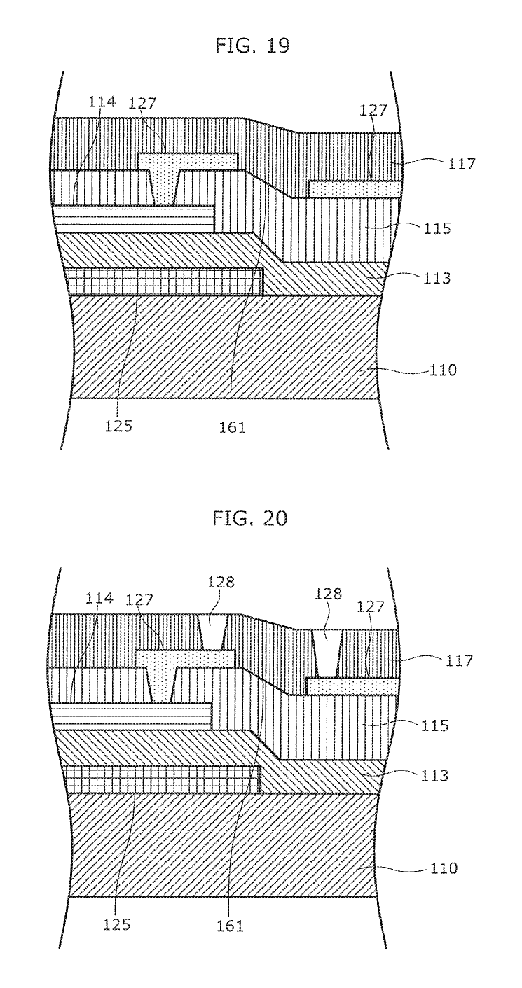

FIG. 19 is a cross-sectional view showing a state in which the third insulating layer has been formed on the second insulating layer through the third insulating layer forming process. Note that this drawing highlights the stepped portions generated by the first pattern.

The third insulating layer forming process refers to a process of forming the third insulating layer 117 to be disposed in a sheet form to cover the second pattern formed on the surface of the second insulating layer 115. Any method may be used to form the third insulating layer 117, as in the case of forming the first insulating layer 113.

The following describes a second contact hole forming process.

FIG. 20 is a cross-sectional view showing a part of the selection transistor after the second contact hole forming process is completed.

The second contact holes 128 are through holes, each passing through the third insulating layer 117 in a thickness direction to ensure an electrical connection with, for example, the drain electrodes 127, which are electrically conductive portions located in the proximity of the both lateral edges of the first disconnect part 161 included in the second pattern. In the present embodiment, the second contact holes 128 are also formed in the electrically conductive portions located in the proximity of the both lateral edges of the second disconnect part 162 and at the electrically conductive portions located in the proximity of the both lateral edges of the third disconnect part 163.

The second contact holes 128 are created by forming a photoresist pattern on the surface of the third insulating layer 117 through a technique such as photolithography, as in the case of the first contact holes 118, and subsequently by using a technique such as dry-etching.

The following describes a third patterning process,

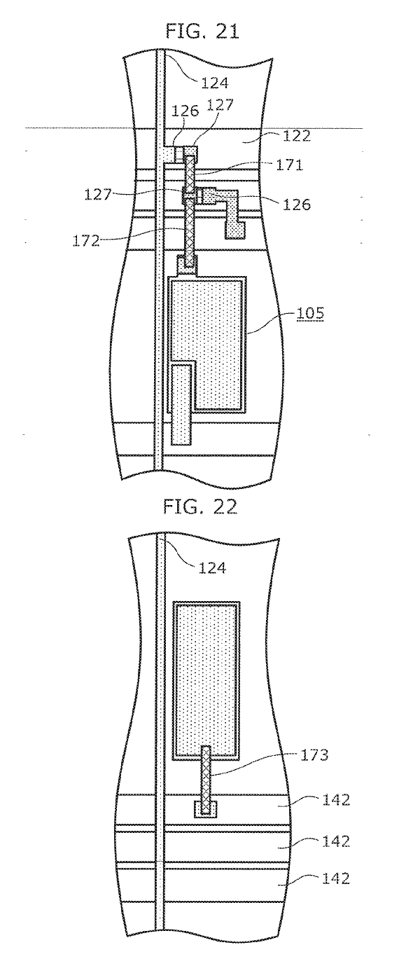

FIG. 21 is a plan view showing a line pattern resulted from the third patterning process.

FIG. 22 is a plan view showing a third pattern formed on the periphery of the substrate.

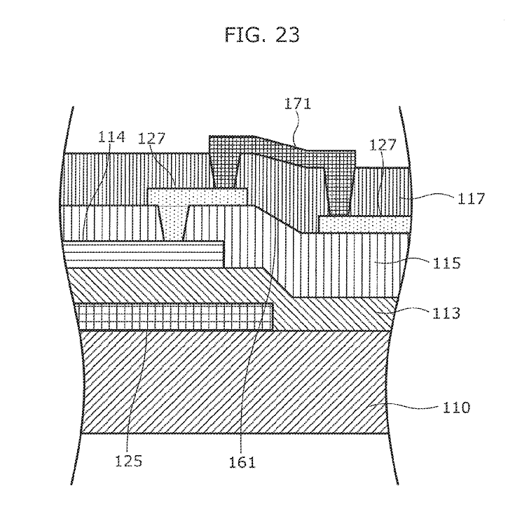

FIG. 23 is a cross-sectional view showing a part of the selection transistor after the third patterning process is completed.

The third patterning process refers to a process of forming a first bridge line 171 and the like on the third insulating layer 117. In the third patterning process according to the present embodiment, a second bridge line 172 and a third bridge line 173 are also formed.

Here, the first bridge line 171 refers to a line of an electrical conductor that electrically connects the data line 124 and the first common line 141. Such electrical connection is established by the first bridge line 171 extending over the first disconnect part 161 in a layer different from that of the second pattern so as to be electrically connected to the conductive portions located in the proximity of the both lateral edges of the first disconnect part 161.

Further, the third bridge line 173 refers to a line of an electrical conductor that electrically connects the data line 124 and the second common lines 142. Such electrical connection is established by third bridge line 173 extending over the third disconnect part 163 in a layer different from that of the second pattern so as to be electrically connected to the conductive portions located in the proximity of the both lateral edges of the third disconnect part 163.

Further, the second bridge line 172 refers to a line of an electrical conductor that electrically connects the drain electrode 127 of the selection transistor 121 and the capacitor 105. Such electrical connection is established by the second bridge line 172 extending over the second disconnect part 162 in a layer different from that of the second pattern so as to be electrically connected to the conductive portions located in the proximity of the both lateral edges of the second disconnect part 162.

The first disconnect part 161 refers to a part that is electrically disconnected in the second pattern, but that is electrically connected for certain in the third pattern. This is applicable to the second disconnect part 162 and the third disconnect part 163.

In the present embodiment, the first disconnect part 161, the second disconnect part 162, and the third disconnect part 163 are disposed at the borders between the portions where the first pattern is formed and the portions where the first pattern is not formed. More specially, these disconnect parts are disposed to extend over the stepped portions generated by the first pattern. Consequently, the first bridge line 171, the second bridge line 172, and the third bridge line 173 are also disposed to extend over the stepped portions.

As described above, the first insulating layer 113, the second insulating layer 115, and the third insulating layer 117 lessens the steepness of the stepped portions, as a result of which slopes that extend between the portions where the first pattern is formed and the portions where the first pattern is not formed are lessened. The use of the first bridge line 171, the second bridge line 172, and the third bridge line 173 to establish an electrical connection reduces the possibility of breaks and thus increases the yield of the organic EL display panel 100 to be manufactured, as compared to the case where an electrical connection is to be established at a relatively steeply sloped portion in the second pattern.

To form the third pattern, an electrically conductive film is formed across the entirety of the surface of the third insulating layer 117 through a technique such as sputtering, as in the case of forming the first pattern. This results in the conductive film disposed also on the inner periphery of each of the second contact holes 128, bringing the conductive film to come into contact with the conductive portions located in the proximity of the both lateral edges of the disconnect parts. Next, a photoresist pattern is formed on the surface of the conductive film through a technique such as photolithography. Unnecessary portions of the conductive film are subsequently etched through a technique such as wet-etching.

This results in the third pattern as shown by the diagonal cross hatched parts in FIGS. 21 and 22.

As described above, the organic EL display panel 100 is manufactured by performing, for a TFT array 101 with no defects found in its data lines 124 by the open-short test and a TFT array 101 that has been repaired, the processes such as the formation of the third insulating film, the formation of the third pattern that includes the first bridge line 171 and the like, and other film formations.

According to the above-described manufacturing method, it is possible to conduct an open-short test for the data lines 124 that are electrically isolated from one another, even in the case where an amorphous oxide semiconductor with a negative threshold voltage is used as the channel forming layer 114. This enables the manufacturing of the organic EL display panel 100 that includes a TFT array 101 having the data lines 124 with no break or short circuit, and thus increases the yield of the organic EL display panel 100.

Furthermore, the above-described manufacturing method is capable of avoiding a break that may occur due to a height difference on the surface on which each pattern is formed, and thus capable of further increasing the yield of the organic EL display panel 100. This is achieved by disposing the disconnect parts of the second pattern at the stepped portions generated by the first pattern and by forming the third pattern, which includes the first bridge line 171 and the like, at the portions where the height differences between the stepped portions have been reduced by the three or more insulating layers.

Note that the present disclosure is not limited to the foregoing embodiment. For example, an embodiment achieved by combining any of the elements described in the present specification or an embodiment achieved by eliminating one or more of the elements described in the present specification may serve as an embodiment of the present disclosure. Moreover, the present disclosure also includes variations achieved by making various modifications to the present disclosure that can be conceived by those skilled in the art without departing from the essence of the present disclosure, i.e., the meaning of the language recited in Claims.

For example, although the present embodiment describes the case of including the second disconnect part 162 in the second pattern, the second disconnect part 162 may alternatively be omitted.

### INDUSTRIAL APPLICABILITY

The technique disclosed herein is widely applicable to the manufacturing of organic EL display panels that include thin-film transistors having amorphous oxide semiconductors.

### REFERENCE SIGNS LIST

101 TFT array
102 Subpixel
105 Capacitive element
110 Substrate
111 Conductive film
112 Photoresist
113 First insulating layer
114 Channel forming layer
115 Second insulating layer
117 Third insulating layer
118 First contact hole
119 Amorphous oxide semiconductor film
121 Selection transistor
122 Scan line
124 Data line
125 Gate electrode
126 Source electrode
127 Drain electrode
128 Second contact hole
133 Charging terminal
134 Power receiving sensor
141 First common line
142 Second common line
151 First electrode
161 First disconnect part
162 Second disconnect part
163 Third disconnect part
171 First bridge line
172 Second bridge line
173 Third bridge line
200 Stage

1. A method for manufacturing an organic EL display panel including selection transistors each having a channel that includes an amorphous oxide semiconductor, the method comprising:
forming, on a substrate which is an insulator, a first pattern that includes
gate electrodes of the selection transistors,
scan lines connected to the gate electrodes, and
a first common line;
forming, above the substrate, a second pattern that includes
source electrodes of the selection transistors,
drain electrodes of the selection transistors,
data lines connected to the source electrodes, and
first disconnect parts that disconnect the data lines and the first common line;
conducting an open-short test for the data lines; and
forming, above the substrate, a third pattern that includes first bridge lines that connect the data lines and the first common line, each of the first bridge lines extending over a corresponding one of the first disconnect parts.

2. The method according to claim 1,
wherein, in the second pattern, each of the first disconnect parts is disposed between a corresponding one of the data lines and a corresponding one of the source electrodes of the selection transistors or in a proximity of a corresponding one of the drain electrodes of the selection transistors.

3. The method according to claim 1,
wherein the second pattern further includes second disconnect parts between the corresponding drain electrodes of the selection transistors and capacitors, the second disconnect parts being discontinuous with the corresponding first disconnect parts, and
the third pattern further includes second bridge lines that connect the corresponding drain electrodes and the capacitors, each of the second bridge lines extending over a corresponding one of the second disconnect parts.

4. The method according to claim 3,
wherein in the second pattern, each of the second disconnect parts is disposed to extend over a border between a portion where the first pattern is formed and a portion where the first pattern is not formed.

5. The method according to claim 1,
wherein the first pattern includes a second common line on a periphery of the substrate,
the second pattern includes third disconnect parts that disconnect the data lines and the second common line, and
the third pattern includes third bridge lines that connect the data lines and the second common line, each of the third bridge lines extending over a corresponding one of the third disconnect parts.

6. An organic EL display panel including selection transistors each having a channel that includes an amorphous oxide semiconductor, the organic EL display panel comprising:
a substrate which is an insulator;
a first pattern that includes gate electrodes of the selection transistors, scan lines connected to the gate electrodes, and a first common line;
a second pattern that includes source electrodes of the selection transistors, drain electrodes of the selection transistors, data lines connected to the source electrodes, and first disconnect parts that disconnect the data lines and the first common line; and
a third pattern that includes first bridge lines that connect the data lines and the first common line, each of the first bridge lines extending over a corresponding one of the first disconnect parts.
